(19) United States
(12) Patent Application Publication
(10) Pub. No.: US 2011/0042138 A1
(43) Pub. Date: Feb. 24, 2011

(54) Electrical utility box having vertical adjustment

(76) Inventor: Todd Dutton, Thousand Oaks, CA (US)

Correspondence Address: Randall L. Owen, 573 Fairfield Road, Simi Valley, CA, 93065, US

(21) Appl. No.: 12/583,727

(22) Filed: Aug. 24, 2009

(51) Int. Cl. H05K 7/14

(52) U.S. Cl. 174/542

(57) ABSTRACT

The present invention relates to electrical wiring components, and more particularly, to an electrical utility box having a mechanism for providing vertical adjustment after attachment to a wall stud, both before and after wall surface installation and during all phases of construction. A first preferred embodiment of the present invention includes an electrical utility box attached to a mounting bracket containing a slot placed longitudinally along the center of the bracket, thereby allowing the electrical utility box to slide along the length of the bracket. A second preferred embodiment includes an electrical utility box and a T-shaped mounting bracket permanently fixed to the electrical box, thereby allowing the combination to be used as a conventional electrical utility box assembly. In addition, an L-shaped optional adjustable mounting bracket to provides a vertical adjustment capability when combined with a T-shaped mounting bracket. A third preferred embodiment includes an electrical utility box attached to a mounting bracket by wrap-around tabs.

### CROSS-REFERENCE TO RELATED PATENT APPLICATIONS

This application claims priority to co-pending U.S. patent application Ser. No. 12/217,431 filed Jul. 3, 2008, incorporated herein by reference in its entirety.

### BACKGROUND OF THE INVENTION

1. Field of the Invention

The present invention relates to electrical wiring components, and more particularly, to an electrical utility box having a mechanism for vertical adjustment after attachment to a wall stud, both before and after wall surfaces have been installed.

2. Description of the Prior Art

Electrical utility boxes are used to hold and position electrical outlets and switches. They are typically constructed of metal or plastic, and are designed to hold combinations of one or more electrical outlets or switches. Conventional electrical boxes further include one or more openings that allow electrical wires to pass through the walls of the box and make electrical connection with the outlets or switches contained therein.

Adjustable mounting assemblies for electrical utility boxes are known, wherein the outlet box is slidably mounted on a bracket secured to a wall stud, whereby the outlet box is adjustable so that the front of the box will be flush with respect to the subsequently applied dry wall or paneling.

For example, U.S. Pat. No. 4,747,506 to Smith et al. discloses an adjustable mounting assembly for an electrical outlet box, in which an adjustment bolt serves as both the mechanism for adjustment and as a stop member to hold the box at the desired position, thereby provide an unlimited adjustment of the outlet box. The Smith patent is concerned only with positioning the front of the electrical box relative to subsequently applied plaster or dry wall and paneling. Smith neither discloses nor suggests an adjustment mechanism for the vertical positioning of an electrical box.

U.S. Pat. No. 7,307,212 to Gretz discloses an electrical box assembly with an internal mounting and flange to seal against air infiltration, in order to insulate and minimize air infiltration through walls. There is no disclosure or suggestion in Gretz to provide any type of positional adjustment.

U.S. Pat. No. 7,179,993 to Rose discloses a universal junction box that includes a cable-securing device with the capability to handle both low voltage and high voltage cable in a safe and effective manner. While the junction box of Rose '993 can be mounted in a multitude of environments and orientations, it only addresses the anchoring of various sizes of cable and commonly used flexible conduit. Rose '993 does not disclose or suggest a mechanism for the vertical positioning of the junction box.

U.S. Pat. No. 7,109,414 to Reynolds discloses a pair of electrical boxes straddling a construction stud in new construction and remodeling, to provide a pair of side by side electrical boxes primarily for containing low voltage distribution modules such as, connector blocks or strips, and wires. Additionally, the Reynolds disclosure pertains to electrical wall boxes that are low voltage wiring systems, including Category (CAT) UPT cables, Coaxial CATV/MATV/CCTV Serial Digital, Computer Network (LAN), and low voltage control and speaker cables, encompassing telephone, computer, internet, video, low voltage lighting, and the like. Reynolds does not disclose or suggest the adjustment or positioning of the electrical boxes.

U.S. Pat. No. 7,109,414 to Johnson et al. discloses an adjustable bracket for securing an electrical box to a stud. More particularly, the bracket displosed in Johnson et al. has an adjustable member to secure an electrical box to studs of different sizes, and of either metal or wood stud. The adjustment mechanism neither discloses or suggests the positioning of an electrical box relative to the wall stud.

U.S. Pat. Nos. 6,929,140 and 7,109,414 to Rose each disclose a universal junction box that includes multiple methods for securing cables, various kinds of wires and conduits and multiple methods for securing the box within a wall cavity. The front side of the box, which can be positioned flush with the installed wall covering, includes fittings for attaching a wall plate, switches, plugs, connectors, and electrical/electronic devices to the box. The junction box allows the addition of an extension to the rear of the junction box for a between-wall design for the installation and attachment of similar devices on an opposing wall surface through the same junction box. The junction box also engages extensions to the side of the junction box allowing two or more ganged box configurations, which share the multiple methods for securing the junction box within a wall cavity. However, there is no disclosure or suggestion in Rose '414 of an adjustment mechanism for vertically positioning the junction box.

U.S. Pat. No. 7,109,414 to Dinh discloses an adjustable electrical outlet box assembly includes an outlet box and a box bracket which is adjustably positioned to the outlet box. The box bracket includes a box attachment portion having a deflectable finger for resilient engagement with a side wall of the box. The bracket further includes a stud attachment portion for engagement with the stud. The bracket is adjustably positioned on the box so that the box may be adjustably positioned such that the open front face of the outlet box lies flush with respect to the surface of the wall board placed over the stud. There is no disclosure or suggestion to provide an adjustment mechanism for vertically positioning the electrical outlet box.

U.S. Pat. No. 6,878,877 to Cozzi et al. discloses an adjustable electrical outlet box assembly comprising an outlet box, an electrical outlet assembly, and an adaptor. The adaptor may be adjusted to different heights, relative to the outlet box, to accommodate different thicknesses for different floor or wall covering materials. Cozzi et al. contains no disclosure or suggestion of an adjustment mechanism for vertically positioning the electrical outlet box.

U.S. Pat. No. 7,312,396 to Gorman discloses an electrical box that provides a vertical adjustment that is limited to floor-mounted configurations. All adjustments on Gorman are made relative to the floor and such adjustments much be made prior to installation of the wall surfaces. There is no disclosure or suggestion in Gorman to provide a vertical adjustment mechanism for electrical boxes that are not floor mounted, nor can the vertical adjustments of Gorma be made after installation of the wall surfaces.

U.S. Pat. No. 7,476,807 to Gretz discloses an electrical box assembly for providing a secure electrical enclosure on walls constructed with steel studs of two conventional sizes. There is no disclosure or suggestion in Gretz to provide any vertical adjustment capability after the electrical box assembly is attached to the steel wall stud.

U.S. Pat. No. 1,795,224 to Mangin discloses a floor-mounted electrical outlet box with an adjustable supporting bracket therefore that can be positioned without preliminary measuring, so that the box will fall flush, with either the plastering or baseboard facing of a wall partition. The main design criteria in Mangin provides an outlet box that moves in and out of the wall to accommodate two variable wall finish dimensions. There is no disclosure or suggestion in Mangin to provide a vertical adjustment capability during all phases of construction.

While some of the prior art electrical outlet boxes provide an adjustment mechanism for wall thickness, none disclose or suggest a vertical positioning adjustment mechanism that provides for adjustment during the rough-in phase, after the rough-in phase, and after the final wall surfaces have been installed.

Accordingly, there is a need for an electrical utility box having an adjustment mechanism that provides for the vertical positioning of the box after attachment to a wall stud, during all construction phases and after the final wall surfaces have been installed, thereby allowing vertical adjustment to made at any time during all phases of a construction project.

### SUMMARY OF THE INVENTION

The present invention relates to electrical wiring components, and more particularly, to an electrical utility box having a mechanism for providing vertical adjustment after attachment to a wall stud, both before and after final wall surfaces have been installed. This mechanism provides a simple and cost-effective alternative to conventional electrical utility boxes, which must be removed and relocated in order to provide a vertical adjustment.

A first preferred embodiment of the present invention comprises an electrical utility box attached to a mounting bracket containing a slot placed longitudinally along the center of the bracket, thereby allowing the electrical utility box to slide along the length of the bracket. The utility box is attached to the bracket with two fasteners that allow the utility box to slide along the face of the wall bracket. The vertical position of the utility box is secured by a set screw that is tightened against the mounting bracket. The set screw is oriented at an angle with its head facing the open front of the utility box, thereby providing an easy means of adjustment of the utility box, even after installation of the wall surface and without the need for special tools.

The first preferred embodiment further comprises a notch on the front edge of the mounting bracket, and a mark on the front edge of the utility box that is attached to the mounting bracket, both used in combination to center the utility box along the mounting bracket. In the preferred embodiment, the electrical utility box and mounting bracket of the present invention will be manufactured so that the default setting would be set to center. This will allow for quick and easy placement of the utility box to the wall stud during its initial placement.

The mounting bracket of the first preferred embodiment of the present invention further incorporates alignment tabs on the front edge of the bracket at both the top and bottom, thereby providing easy setting of the utility box and mounting bracket assembly flush to the front face edge of the wall stud. These alignment tabs, bent at a 90 degree angle from the face of the bracket, act as stops so that the bracket aligns flush with the face of the wall stud so that the proper preset of the box offset of either ½ or ⅝ is maintained. Further, the first embodiment includes a preset offset for either a ½ or ⅝ inch wall finish thickness. This eliminates the need for a mud ring, which is used with conventional electrical utility boxes to flush the box out to the final wall finish. The two offsets (½ or ⅝ inch), cover the two most common wall thicknesses in residential construction.

A second preferred embodiment of the present invention comprises an electrical utility box with a T-shaped mounting bracket permanently fixed to the electrical box, thereby allowing the electrical utility box to be used as a conventional electrical utility box assembly. In addition, an L-shaped optional adjustable mounting bracket provides a vertical adjustment capability. If an installer is uncertain as to the exact elevation of some of the boxes on a job, the installer can use the optional L-shaped adjustable mounting bracket with the utility box to provide easy adjustments of those boxes at a later time when the design issues have been finalized. This allows the installer to move forward with the rough-in phase of his work, and makes for a fast and easy task of moving those utility boxes at a later time, both before and after the wall surfaces have been installed.

The optional adjustable mounting bracket of the third preferred embodiment includes an L-shaped adjustable bracket to straddle the wall stud, further including multiple holes for securing the mounting bracket to the wall stud, and a U-shaped channel on the inside face of the bracket to receive the T-shaped mounting bracket that is permanently fixed to the utility box. The L-shape mounting bracket serves two purposes. The first is to assure that the L-shaped adjustable bracket properly meets the front of the wall stud. As with the first and second embodiments discussed above, the third preferred embodiment includes a predetermined offset option of ½ or ⅝ inch. Once attached to the wall stud, the L-shaped bracket allows the T-shaped mounting bracket to easily slide into the U-shaped channel on the inside face of the L-shaped adjustable bracket. This keeps the utility box in perfect alignment to the offset requirements of the wall thickness.

The second purpose of the L-shaped adjustable bracket is to allow the utility box to slide along the length of the L-shaped adjustable bracket. Specifically, the T-shaped mounting bracket slides along the U-shaped channel of the L-shaped adjustable bracket. As with the first and second embodiments of the present invention, the movement of the utility box along the L-shaped adjustable bracket is secured by a set screw located in the wall of the utility box adjacent to the T-shaped mounting bracket.

A third preferred embodiment of the present invention comprises an electrical utility box attached to a mounting bracket by wrap-around tabs. The wrap-around tabs are formed as a part of the utility box and are designed to straddle the mounting bracket with a small gap between the side of the bracket and the face of the utility box, thereby allowing the utility box to slide along the length of the mounting bracket. As with the first embodiment, The vertical position of the utility box is secured by a set screw that is tightened against the mounting bracket.

All other features of the first preferred embodiment apply to the second and third preferred embodiments, including the center marks on the utility box and mounting bracket, the alignment tabs on the mounting bracket, and the ½ and ⅝ inch offset selections.

One object of the present invention is to provide an improved electrical utility box having a vertical adjustment mechanism, both before and after installation of the wall surfaces.

Another object of the present invention is to provide an electrical utility box whose position can be easily adjusted without repositioning its mounting bracket.

Still another object is to provide an electrical utility box that can be used in both residential and commercial applications.

Yet another of the present invention is to provide an electrical utility box that can be adjusted during all phases of a construction project.

These and other features and advantages of the present invention will be appreciated by a review of the following detailed-description of the preferred embodiments taken in conjunction with the following drawings.

### BRIEF DESCRIPTION OF THE DRAWINGS

The present invention may be best understood by referring to the following detailed description of the preferred embodiments and the accompanying drawings, wherein like numerals denote like elements, and in which:

FIG. 1 is a perspective view of a first embodiment of an electrical utility box 100, constructed according to the principles of the present invention;

FIG. 2 is a top view of electrical utility box 100, showing the vertical adjustment mechanism;

FIG. 3 is a front view of electrical utility box 100, showing the set screw and mounting tabs for electrical components such as outlets or switches;

FIG. 4 is a side view of electrical utility box 100, showing the available range of vertical adjustment;

FIG. 5 is a perspective view of a second embodiment of an electrical utility box 200, constructed according to the principles of the present invention;

FIG. 6 is a top view of electrical utility box 200, showing the vertical adjustment mechanism;

FIG. 7 is a front view of electrical utility box 200, showing the available range of vertical adjustment;

FIG. 8 is a side view of electrical utility box 200, also showing the available range of vertical adjustment;

FIG. 9 is a perspective view of a third embodiment of an electrical utility box 300, constructed according to the principles of the present invention;

FIG. 10 is a side view of electrical utility box 300, showing the vertical adjustment mechanism;

FIG. 11 is a front view of electrical utility box 300, showing the available range of vertical adjustment; and

FIG. 12 is a top view of electrical utility box 300, also showing the vertical adjustment mechanism.

### DETAILED DESCRIPTION OF THE PREFERRED EMBODIMENTS

The following exemplary discussion focuses on an electrical utility box that provides a vertical adjustment mechanism, the latter allowing for vertical positioning both before and after final wall surfaces have been installed, and during all phases of construction.

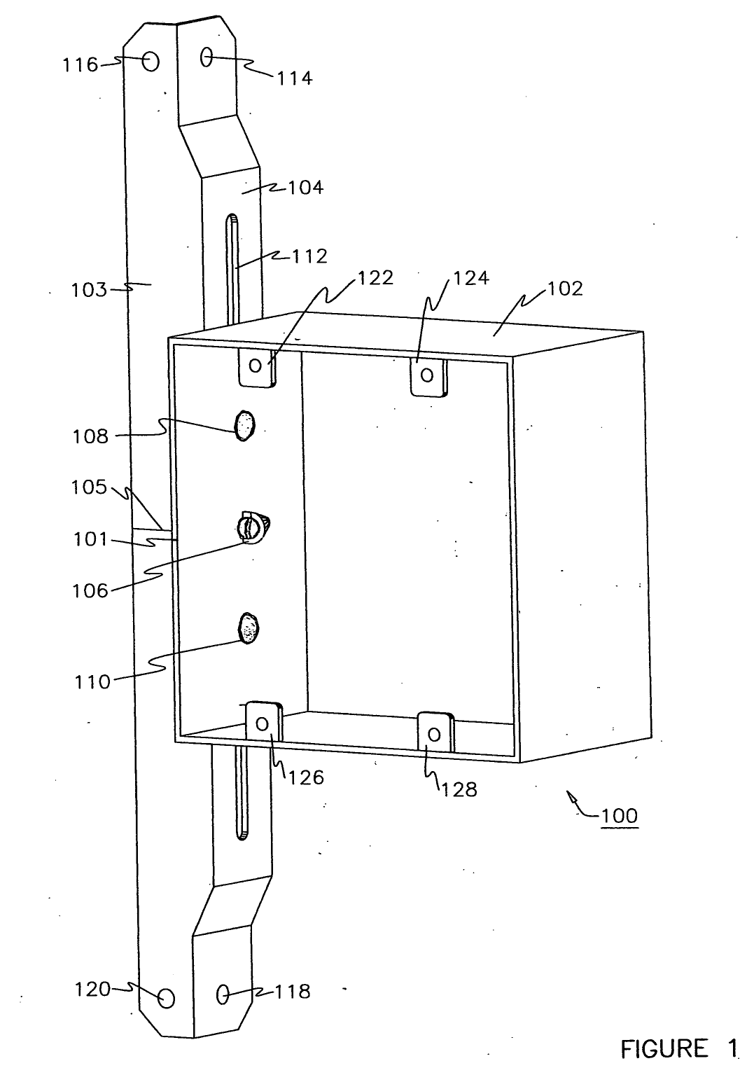

Referring now to FIG. 1, a perspective view of a first preferred embodiment of an electrical utility box assembly 100, constructed in accordance with the present invention, is shown. Electrical utility box assembly 100 comprises an electrical utility box 102 attached to a mounting bracket 104, the latter containing a slot 112 placed longitudinally along the center of bracket 104, thereby allowing electrical utility box 102 to slide along the length of bracket 104. Mounting bracket 104 includes mounting holes 114-120 for attaching electrical utility box assembly to a wall stud or other attachment point, using conventional nails or screws (not shown). Utility box 102 is attached to mounting bracket 104 with two fasteners 108-110 that pass through slot 112 and allow utility box 102 to slide along the face of bracket 104. The vertical position of utility box 102 is secured by a set screw 106 that is tightened against mounting bracket 104. Set screw 106 is oriented at an angle with its head facing the open front of utility box 102, thereby providing an easy means of vertical adjustment of utility box 102 during all phases of construction and without requiring special tools.

The first preferred embodiment further comprises a notch 105 on a front edge 103 of mounting bracket 104, and a mark 101 on a side of utility box 102 that is adjacent to mounting bracket 104. Mark 101 and notch 105 are used in combination to center utility box 102 along mounting bracket 104. In the preferred embodiment, utility box 102 and mounting bracket 104 may be manufactured so that the default setting between utility box 102 and mounting bracket 104 is set to center. This will allow for quick and easy placement of electrical utility box assembly 100 to a wall stud during its initial placement.

Mounting bracket 104 aligns flush with utility box 102 to a proper preset offset of either ½ or ⅝ inch from the face of the wall stud. Further, the first embodiment includes a preset offset for either a ½ or ⅝ inch wall finish thickness. This eliminates the need for a mud ring, which is used with conventional electrical utility boxes to align the box with the final wall finish. The two offsets (½ or ⅝ inch), cover the two most common wall thicknesses in residential construction.

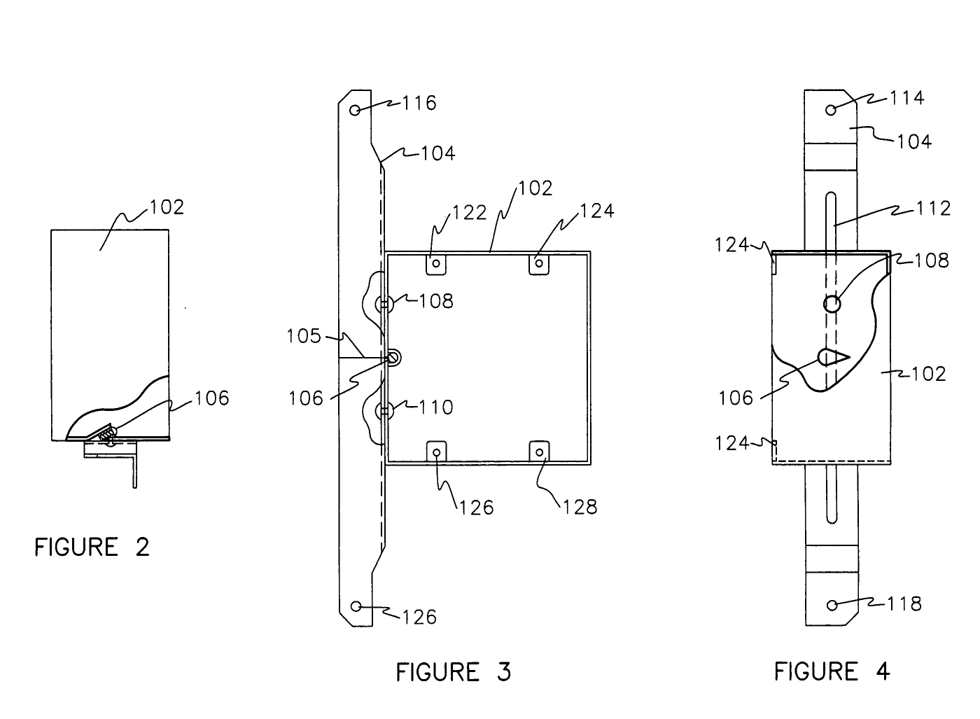

FIG. 2 is a top view of electrical utility box assembly 100, including a cut-away portion of utility box 102 showing the angled positioning of set screw 106 relative to utility box 102 and mounting bracket 104. Set screw 106 provides a frictional force which holds utility box 102 in position along mounting bracket 104.

FIG. 3 is a front view of utility box assembly 100, showing utility box 102 centered on mounting bracket 104. FIG. 3 also provides a cut-away view showing how fasteners 108 and 110 pass through slot 102 to provide an slidably adjustable attachment between utility box 102 and mounting bracket 104. Also shown are tabs 122-128 that are used to mount conventional electrical switches, receptacles, low-voltage outlets, and similar electrical components to utility box 102. Also shown in FIG. 3 are mounting holes 116 and 120, which were described above in connection with FIG. 1.

FIG. 4 is a side view of utility box assembly 100, including a cut-away portion of utility box 102 showing the position of fastener 108 in relation to slot 112 of mounting bracket 104. FIG. 4 also provides another view of set screw 106, which is used to fix the position of utility box 102 along mounting bracket 104. Also shown in FIG. 4 are mounting holes 114 and 118, which were described above in connection with FIG. 1.

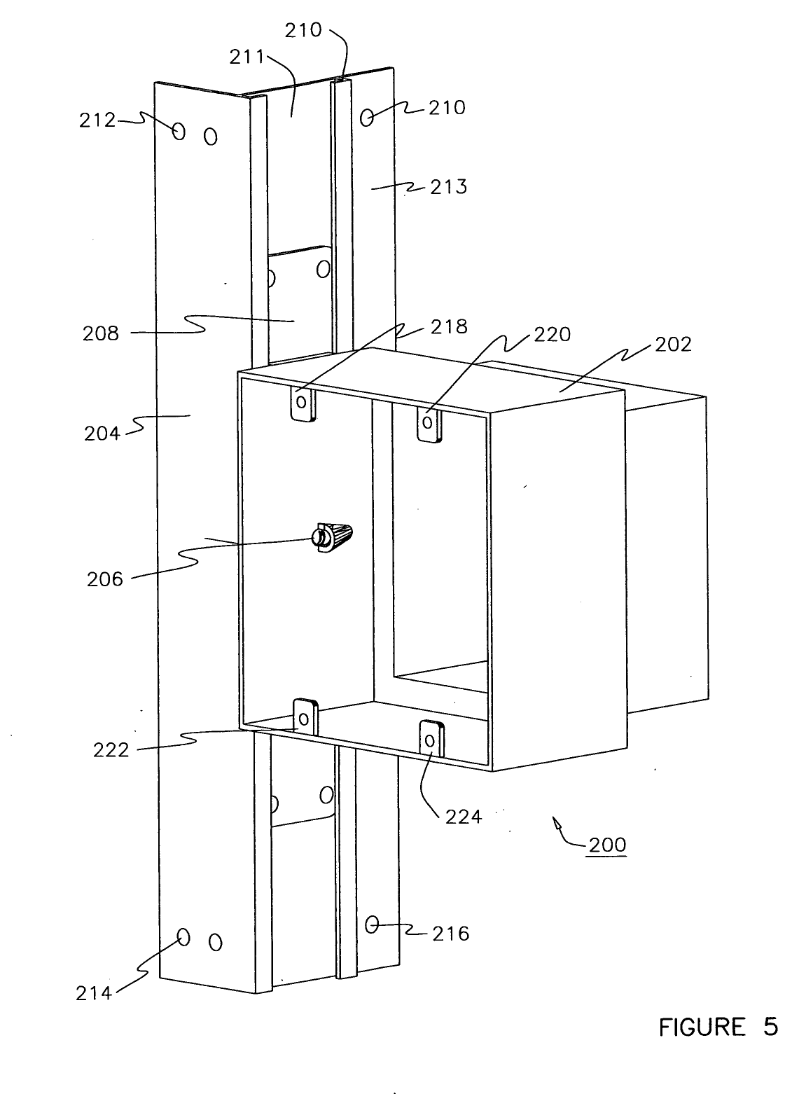

Referring now to FIG. 5, a perspective view of a second preferred embodiment of an electrical utility box assembly 200, constructed in accordance with the present invention, is shown. Electrical utility box assembly 200 comprises an electrical utility box 202 and a T-shaped mounting bracket 208 permanently fixed to utility box 202, thereby allowing the combination to be used as a conventional electrical utility box assembly. In addition, electrical utility box assembly 200 includes an L-shaped adjustable mounting bracket 204 containing a U-shaped channel 211 on its inside face 213, in which T-shaped mounting bracket 208 can fit, thereby allowing electrical utility box 202 to slide along the length of L-shaped adjustable mounting bracket 204.

More particularly, L-shaped adjustable mounting bracket 204 serves two purposes. The first is to assure that L-shaped adjustable mounting bracket 204 properly meets the offset requirements of the wall thickness. As with the first embodiment discussed above, electrical utility box assembly 200 includes an offset option of ½ or ⅝ inch. Once attached to the wall stud, L-shaped bracket 204 allows T-shaped mounting bracket 208 to easily slide into U-shaped channel 211 on its inside face 213. This keeps utility box 202 in alignment with the offset requirements of the wall thickness. In addition, L-shaped adjustable mounting bracket 204 is designed to fit on the corner of a wall stud, and further includes multiple mounting holes 210-216 for securing L-shaped adjustable mounting bracket 204 to the wall stud.

The second purpose of L-shaped adjustable mounting bracket 204 is to allow utility box 202 to slide along the length of L-shaped adjustable mounting bracket 204. Specifically, T-shaped mounting bracket 208 fits into, and slides along, U-shaped channel 211 of L-shaped adjustable mounting bracket 204. As with the first embodiment of the present invention, the position of utility box 202 along L-shaped adjustable mounting bracket 204 is secured by a set screw 206 located in the wall of the utility box 202 adjacent to T-shaped mounting bracket 208.

Using electrical utility box assembly 200, if an installer is uncertain as to the exact elevation of some of the electrical utility boxes on a construction job, he or she can use the optioner L-shaped adjustable mounting bracket 204 in combination with T-shaped mounting bracket 208 and utility box 202 to provide easy adjustments of certain boxes at a later time when the design issues have been finalized. This allows the installer to move forward with the rough-in phase of his or her work, and provides a fast and easy way of moving those utility boxes at a later time.

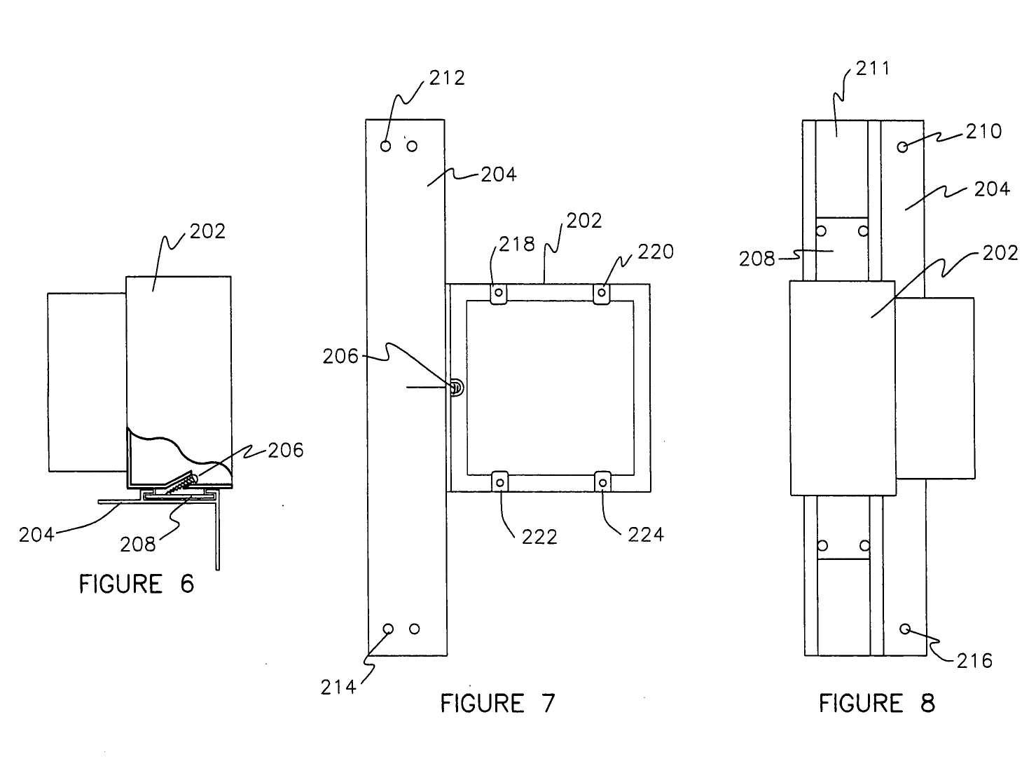

FIG. 6 is a top view of electrical utility box assembly 200, including a cut-away portion of utility box 202 showing the angled positioning of set screw 206, utility box 202, T-shaped mounting bracket 208, and L-shaped adjustable mounting bracket 204.

FIG. 7 is a front view of utility box assembly 200, showing utility box 202 centered on L-shaped adjustable mounting bracket 204. Also shown are tabs 218-224 that are used to mount conventional electrical switches, receptacles, and similar electrical components to utility box 202. Also shown in FIG. 7 are mounting holes 212 and 214, which are used to attach L-shaped adjustable mounting bracket 204 to a wall stud, and mounting holes 210 and 216 shown in FIG. 8, which are used to attach T-shaped mounting bracket on the inside face of a wall stud.

FIG. 8 is a side view of utility box assembly 200, including a cut-away portion of utility box 202 showing the position of T-shaped mounting bracket 208 in relation to U-shaped channel 211 of L-shaped adjustable mounting bracket 204. Also shown in FIG. 8 are mounting holes 210, 216 and 212 and 214, which were described above in connection with FIG. 5.

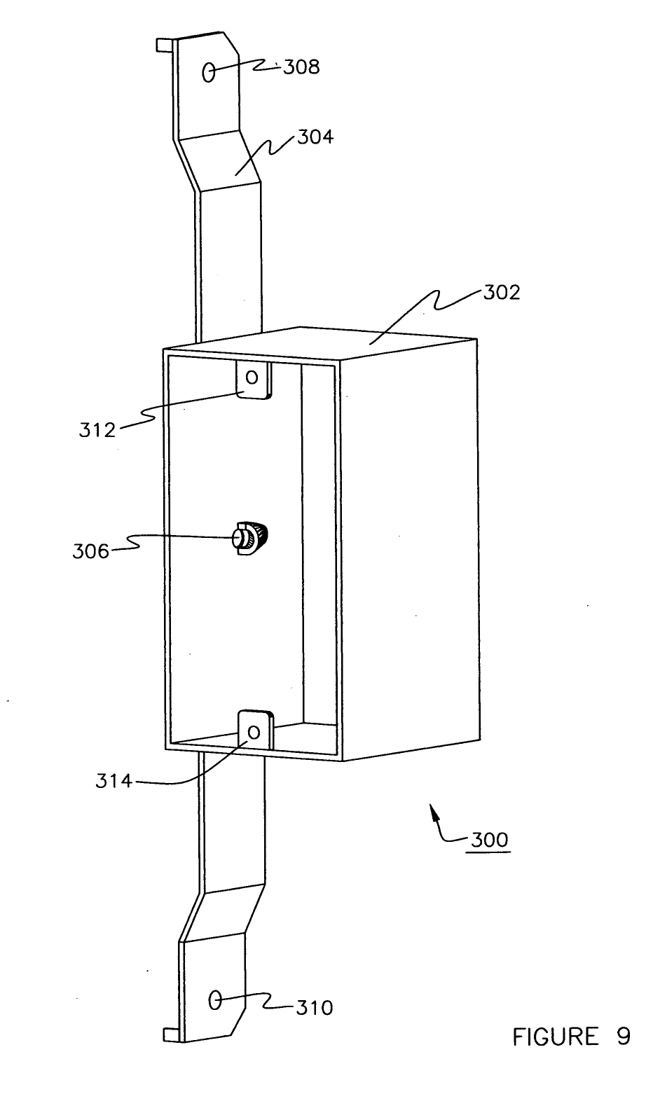

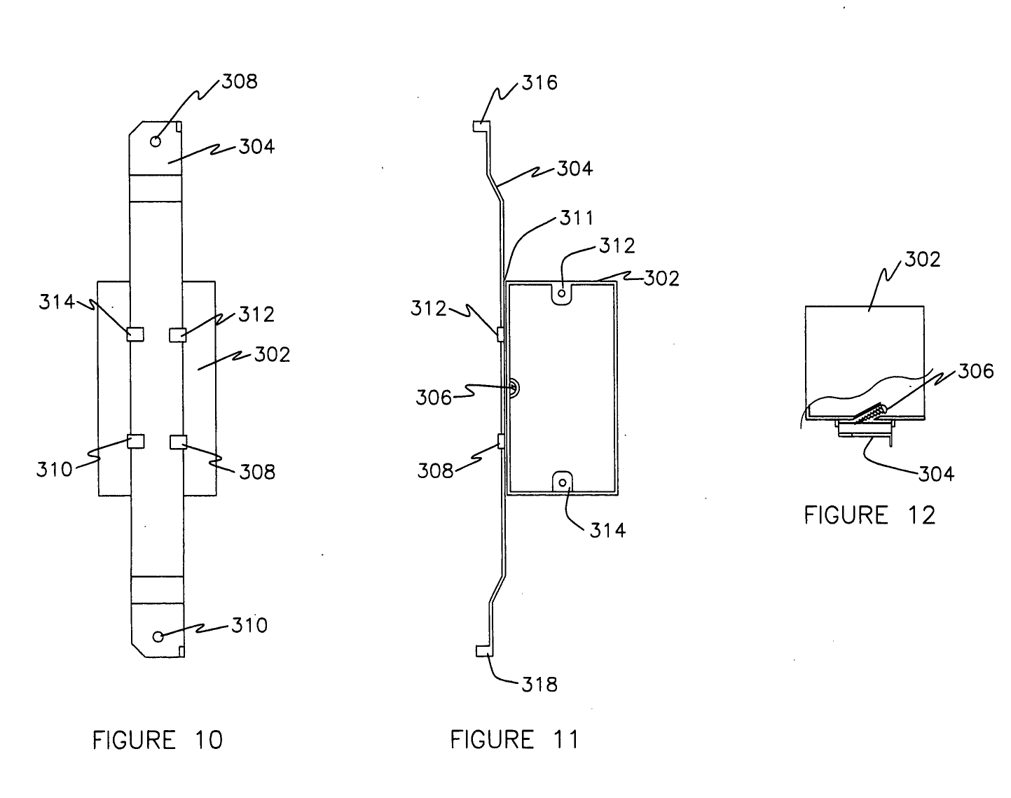

FIG. 9 is a perspective view of a third preferred embodiment of an electrical utility box assembly 300, constructed in accordance with the present invention, Electrical utility box assembly 300 comprises an electrical utility box 302 and a mounting bracket 304 attached to electrical box 302 by wrap-around tabs 308-312 (see FIG. 10). Wrap-around tabs 308-312 are formed as a part of utility box 302 and are designed to straddle mounting bracket 304 with a small gap 311 (see FIG. 11) between the side of mounting bracket 304 and the adjacent face of utility box 302, thereby allowing the latter to slide along the length of mounting bracket 304. As with the first and second embodiments, the vertical position of utility box 302 is secured by a set screw 306 that is tightened against mounting bracket 304.

FIG. 10 is a side view of electrical utility box assembly 300, showing the position of wrap-around tabs 308-312 in relation to utility box 302 and mounting bracket 304. Also shown in FIG. 10 are mounting holes 308 and 310 for attaching electrical utility box assembly 300 to a wall stud.

FIG. 11 is a front view of utility box assembly 300, showing utility box 302 centered on mounting bracket 304. Also shown are tabs 312 and 314 that are used to mount conventional electrical switches, receptacles, and similar electrical components to utility box 302. Also shown is gap 311 between utility box 302 and mounting bracket 304.

FIG. 12 is a top view of utility box assembly 300, including a cut-away portion of utility box 302 showing the position of set screw 306 in relation to utility box 302 and mounting bracket 304.

All other features of the first and second preferred embodiments apply to the third preferred embodiment, including the center marks on the utility box and mounting bracket, the alignment tabs on the mounting bracket, and the ½ and ⅝ inch offset selections.

The advantages of the present invention over the prior art are that the present invention allows adjustments in the vertical of electrical boxes used to hold outlets, switches, lights, and low voltage accessories, both before and after final wall finishes are applied to wall studs in the construction of single- and multi-family residential homes, as well commercial buildings. Currently, there are no products available that allow easy vertical adjustment for and electrical utility box after the latter has been attached to the wall stud. The following are examples of the use of the present invention in several phases of the construction of residential homes and multifamily structures.

The adjustment capability of the present invention before wall finishes are applied (e.g., drywall, stucco, plaster, siding, tile, etc.) is simple and fast. Simply loosen the set screw located inside the utility box and adjust the box up or down to the desired elevation, then retighten the set screw. With conventional electrical utility boxes, the task is complicated by having to remove multiple screws or set nails from the fixed wall bracket, moving the box, then reattaching the box. This process is both time-consuming and costly.

The amount of vertical adjustment provided by the present invention is dependent on the length of wire left inside the electrical box, which the electrical installer can determine at the time of installing of wire. In cases in which the exact height of the electrical box is in question at the time of installation, the electrical installer can allow extra wire to extend through the utility box of the present invention until the exact vertical position of the box is determined.

The above example is a very common occurrence in bathrooms and kitchens, where tile patterns and wood wainscoting affects the placement of electrical outlets, switches and light fixture boxes. If the desired vertical position is not accurately determined prior to the placement of drywall onto the interior side of the wall, the vertical adjustment of the utility box of the present invention provides a simple and cost-effective solution. Simply cut the drywall above or below (depending on whether the box needs to move up or down) the wall opening to the exact width of the opening of the outlet or switch and the height of the required movement. Loosen the set screw inside the utility box and slide the box up or down, then retighten the set screw.

Using the present invention, the amount and cost of drywall patching needed is substantially reduced. In fact, the cutout piece can be used to patch the remaining opening that occurs above or below the utility box. For example, a single gang outlet box requiring a four inch raise in elevation would require a 2 inch wide by 4 inch drywall cutout. This cutout piece could then be used to fill in the opening below the raised box, thereby reducing the cost of drywall repair. The amount of drywall removal to change the vertical position of a conventional outlet box is much larger, (usually 10 inches by 10 inches) since the adjustment requires a very large cutout to allow access for the electrician to remove the screws or nails securing the box to the wall.

More importantly, the cutout piece could not be used in the patching of the new opening, thus requiring additional patching materials. The largest cost-saving feature of the present invention is that any tradesman can make the adjustment to the vertical position of the utility box, usually after the electrician has completed their rough-in phase. Most changes occur after the electrician is off the job while other phases of work are being performed by other trades, and often following the installation of the wall surfaces. The present invention provides for fast and easy vertical adjustments to utility boxes, thereby expediting all phases of down line work.

The simple design of the present invention allows for the same production costs as of similar electrical boxes that have a fixed side mount attachment bracket. The present invention can be used with all metal and plastic utility box configurations, including single gang, double gang, triple gang and quad boxes. For example, the embodiments presented in this patent application are intended to be used with both plastic and metal utility boxes and brackets.

Virtually every construction project has electrical utility boxes that require up to several inches of vertical adjustment following initial attachment to a wall stud. In the most extreme cases, however, utility box adjustment in kitchen and bathroom backsplash areas can be up to four to six inches. This is mostly due to tile patterns using decorative tiles that extend outward from the face of the field tile, thus making the cover plate of the switch or outlet uneven with the face of the main tile surface. As mentioned at the beginning of the present application, these changes usually occur after the electrician has completed their box setting phase according to the construction conditions that were known at that time. There are similar situations on projects where other areas of the building are affected by wall finish schedules that change after the completion of drywall that makes the electrical utility box of the present invention a cost-effective tool.

The foregoing description includes what are at present considered to be preferred embodiments of the invention. However, it will be readily apparent to those skilled in the art that various changes and modifications may be made to the embodiments without departing from the spirit and scope of the invention. For example, the utility boxes and mounting brackets may be constructed of metal or plastic as required by specific building codes. Additionally, the utility boxes may hold one or more switches, receptacles, or other devices. Accordingly, it is intended that such changes and modifications fall within the spirit and scope of the invention, and that the invention be limited only by the following claims.

What is claimed is:

1. An electrical utility box assembly, comprising the combination of:
a electrical utility box having four side portions, a back portion, and a front opening;
a mounting bracket having a longitudinal axis;
means for attaching said electrical utility box to said mounting bracket, such that said electrical utility box slides along said longitudinal axis of said mounting bracket; and
means for fixing said electrical utility box along said longitudinal axis of said mounting bracket, said means for fixing accessible through said front opening of said electrical utility box;
whereby said electrical utility box assembly provides for vertical adjustment of said electrical utility box both before and after installation of wall surfaces.

2. The electrical utility box assembly of claim 1, wherein said electrical utility box contains one or more electrical components, said electrical components further comprising a combination of electrical switches and receptacles.

3. The electrical utility box assembly of claim 1, wherein said electrical utility box is constructed of metal.

4. The electrical utility box assembly of claim 1, wherein said electrical utility box is constructed of plastic.

5. The electrical utility box assembly of claim 1, wherein said mounting bracket is constructed of metal.

6. The electrical utility box assembly of claim 1, wherein said mounting bracket is constructed of plastic.

7. The electrical utility box assembly of claim 1, wherein said mounting bracket further comprises a slot placed along longitudinal axis of said mounting bracket, and said means for attaching comprises at least two rivets that pass through a side of said electrical utility box and through said slot, thereby allowing said electrical utility box to slide along a portion of said mounting bracket.

8. The electrical utility box assembly of claim 1, wherein said mounting bracket further comprises a plurality of mounting holes for attaching said mounting bracket to a wall stud.

9. The electrical utility box assembly of claim 1, wherein said means for attaching further comprises a pair of fasteners connecting said electrical utility box to said slot of said mounting bracket.

10. The electrical utility box assembly of claim 1, wherein said means for attaching further comprises a plurality of tabs attached to a side of said electrical utility box, said tabs for receiving said mounting bracket.

11. The electrical utility box assembly of claim 1, wherein said means for attaching further comprises a fixed mounting bracket attached to said electrical utility box, and said mounting bracket further comprises a channel for receiving said fixed mounting bracket.

12. The electrical utility box assembly of claim 1, wherein said means for fixing further comprises a set screw, said set screw for applying friction to hold said electrical utility box at a desired location, and said set screw accessible from said front opening of said utility box.

13. An electrical utility box assembly, comprising:
a electrical utility box for holding one or more electrical components disposed within said electrical utility box, said electrical components including a combination of electrical switches, receptacles and low-voltage components;
a mounting bracket having a longitudinal axis;
means for attaching said electrical utility box to said mounting bracket, such that said electrical utility box slides along said longitudinal axis of said mounting bracket; and
means for fixing said electrical utility box along said longitudinal axis of said mounting bracket;
whereby said electrical utility box assembly provides for vertical adjustment of said electrical utility box during all phases of construction.

14. The electrical utility box assembly of claim 13, wherein said means for attaching further comprises a pair of fasteners connecting said electrical utility box through a slot disposed along said longitudinal axis of said mounting bracket.

15. The electrical utility box assembly of claim 13, wherein said means for attaching further comprises a plurality of tabs attached to a side of said electrical utility box, said tabs for wrapping around an outside edge of said mounting bracket.

16. The electrical utility box assembly of claim 13, wherein said means for attaching further comprises a fixed mounting bracket attached to said electrical utility box, and said mounting bracket further comprises a channel for receiving said fixed mounting bracket.

17. The electrical utility box assembly of claim 13, wherein said means for fixing further comprises a set screw, said set screw for applying friction to hold said electrical utility box at a desired position along said mounting bracket, and said set screw accessible through a front opening of said electrical utility box.

18. The electrical utility box assembly of claim 13, wherein said electrical utility box is constructed of metal.

19. The electrical utility box assembly of claim 13, wherein said electrical utility box is constructed of plastic.

20. The electrical utility box assembly of claim 13, wherein said mounting bracket is constructed of metal.

21. The electrical utility box assembly of claim 13, wherein said mounting bracket is constructed of plastic.
